(19) United States
(12) Patent Application Publication
(10) Pub. No.: US 2007/0026597 A1
(43) Pub. Date: Feb. 1, 2007

(54) Method of manufacturing semiconductor device

(76) Inventor: Kazuaki Nakajima, Kamakura-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/494,742

(22) Filed: Jul. 28, 2006

(30) Foreign Application Priority Data
Jul. 29, 2005 (JP) 2005-221354

(51) Int. Cl. H01L 21/8234

(52) U.S. Cl. 438/197

(57) ABSTRACT

A method of manufacturing a semiconductor device including a MOS transistor includes: forming a gate electrode on a semiconductor substrate via a gate insulating film; performing ion implantation on the semiconductor substrate using the gate electrode as a mask, and performing a heat treatment, thereby forming a diffusion layer in the semiconductor substrate; depositing an insulating film on the gate electrode and the semiconductor substrate to bury the insulating film in the gate electrode; flattening the insulating film to expose an upper surface of the gate electrode; selectively forming a metal film only on the gate electrode; and changing a material of the gate electrode to a metal compound using a metal in the metal film.

### CROSS-REFERENCE TO RELATED APPLICATION

This application is based upon and claims the benefit of priority from prior Japanese Patent Application No. 2005-221354, filed on Jul. 29, 2005, the entire contents of which are incorporated herein by reference.

### BACKGROUND OF THE INVENTION

1. Field of the Invention

The present invention relates to a method of manufacturing a semiconductor device. In particular, the present invention relates to a method of manufacturing a MIS type transistor using a conductor film to form a gate electrode.

2. Background Art

Conventionally, miniaturization of devices has been sought in order to improve the performance of MOSFETs. However, devices in the 0.1 μm or later generation are said to have a limit in scaling of gate oxide film. The reason for this is that as the thickness of a gate oxide film becomes thinner, the increase in gate leakage current caused by tunnel current becomes remarkable. Furthermore, in the aforementioned generations, the depletion in gate electrode cannot be ignored, and it is not possible to decrease the effective oxide thickness as expected.

In order to solve the aforementioned problems, the improve in dielectric constant of a gate insulating film or the use of a metal gate electrode are studied. The former method intends to curb the tunnel current by replacing the gate insulating film with a high-k film to increase the physical film thickness. The latter method intends to prevent the depletion of the gate electrode by changing a material of the gate electrode from a poly-silicon to a metal compound.

In particular, recently, the development of high-k gate insulating film materials is actively performed. New materials such as ZrO₂ and HfO₂ are taken as a subject of academic conferences. The decrease in effective oxide thickness is sought.

However, so far, such materials have not been developed successfully enough so that the reliability etc. of such materials can be-argued as in the case of silicon oxide film. Accordingly, it is considered to take a long time to realize a semiconductor device using such new materials.

On the other hand, the study of metal gate electrodes is not so actively performed as compared with the development of high-k films. However, as shown in the roadmap included in ITRS (International Technology Roadmap for Semiconductors) 2001 Edition, it is considered to be difficult to form a transistor using a conventional polycrystalline silicon electrode in a region where the physical film thickness is 1.2 nm or less.

The difference between the depletion of the gate electrode and the effective oxide thickness is about 0.3 nm. It is said that the development of metal gate electrodes is necessary to elongate the life of silicon type oxide film in such a generation.

In particular, since a fully silicided electrode process is superior in matching property with respect to a conventional CMOS process, the development of such a process is actively performed.

However, since the fully silicided electrode process is limited by the Ni atom diffusion, the thickness or the silicide composition of a silicide layer depend on the gate electrode width.

Furthermore, since the thickness of a silicide layer varies not only depending on the gate length but also depending on the impurity, it is difficult to form a uniform silicide layer in all the gate electrodes.

As described above, it is difficult to stably form a uniform silicide electrode using the fully silicided electrode process in accordance with a conventional method of manufacturing a semiconductor device.

### SUMMARY OF THE INVENTION

A method of manufacturing a semiconductor device including a MOS transistor according to a first aspect of the embodiment of the present invention includes: forming a gate electrode on a semiconductor substrate via a gate insulating film; performing ion implantation on the semiconductor substrate using the gate electrode as a mask, and performing a heat treatment, thereby forming a diffusion layer in the semiconductor substrate; depositing an insulating film on the gate electrode and the semiconductor substrate to bury the insulating film in the gate electrode; flattening the insulating film to expose an upper surface of the gate electrode; selectively forming; and changing a material of the gate electrode to a metal compound using a metal in the metal film.

A method of manufacturing a semiconductor device including at least a first MOS transistor and a second MOS transistor according to a second aspect of the embodiment of the present invention includes:

in order to form the first MOS transistor and the second MOS transistor,

forming a gate electrode on a semiconductor substrate via a gate insulating film;

performing ion implantation on the semiconductor substrate using the gate electrode as a mask, and performing a heat treatment, thereby forming a diffusion layer in the semiconductor substrate;

depositing an insulating film on the gate electrode and the semiconductor substrate to bury the insulating film in the gate electrode; and

flattening the insulating film to expose an upper surface of the gate electrode,

in order to manufacture the first MOS transistor,

selectively forming to change a material of the gate electrode to a first metal compound using the first metal film, and

in order to manufacture the second MOS transistor, selectively forming to change a material of the gate electrode to a second metal compound using the second metal film.

### BRIEF DESCRIPTION OF THE DRAWINGS

FIGS. 1(a) to 1(c) are sectional views for explaining steps of a method of manufacturing a semiconductor device according to a first embodiment of the present invention.

FIGS. 2(a) to 2(c) are sectional views for explaining steps of a method of manufacturing a semiconductor device according to a second embodiment of the present invention.

FIGS. 3(a) to 3(c) are sectional views for explaining steps of a method of manufacturing a semiconductor device according to a third embodiment of the present invention.

FIGS. 4(a) and 4(b) are sectional views for explaining steps following the step shown in FIG. 3(c) of the method of manufacturing a semiconductor device according to the third embodiment of the present invention.

FIGS. 5(a) to 5(c) are sectional views for explaining steps in Example 1 of a method of manufacturing a semiconductor device, which the present inventor knows.

FIGS. 6(a) and 6(b) are sectional views for explaining steps following the step shown in FIG. 5(c) of Example 1 of the method of manufacturing a semiconductor device, which the present inventor knows.

FIGS. 7(a) to 7(c) are sectional views for explaining steps in Example 2 of a method of manufacturing a semiconductor device, which the present inventor knows.

FIGS. 8(a) to 8(b) are sectional views for explaining steps following the step shown in FIG. 7(c) of Example 2 of the method of manufacturing a semiconductor device, which the present inventor knows.

### DESCRIPTION OF THE EMBODIMENTS

Before the embodiments of the present invention, a method of manufacturing a semiconductor device known by the present inventors will be described below.

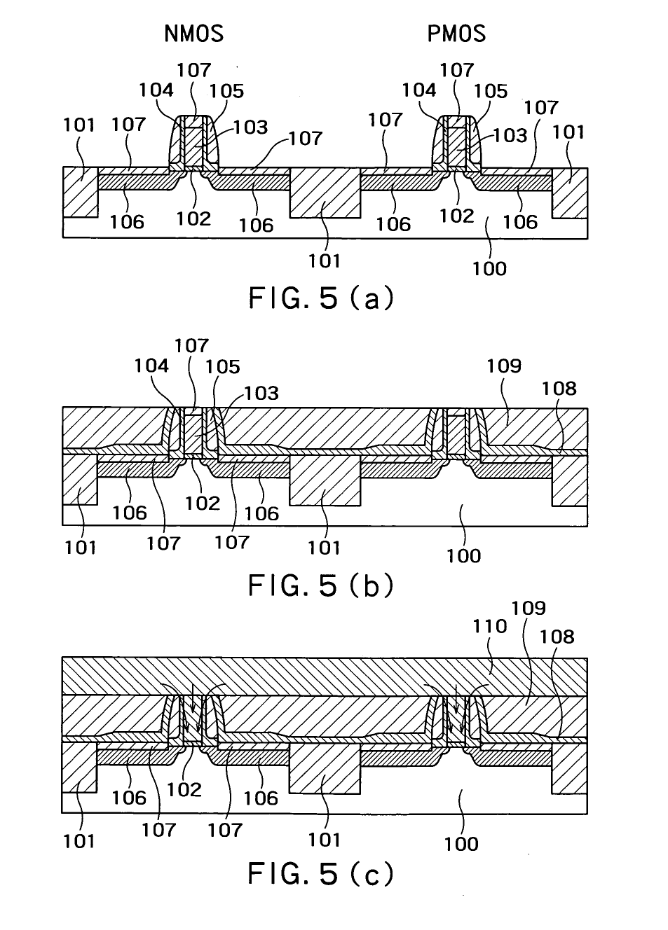

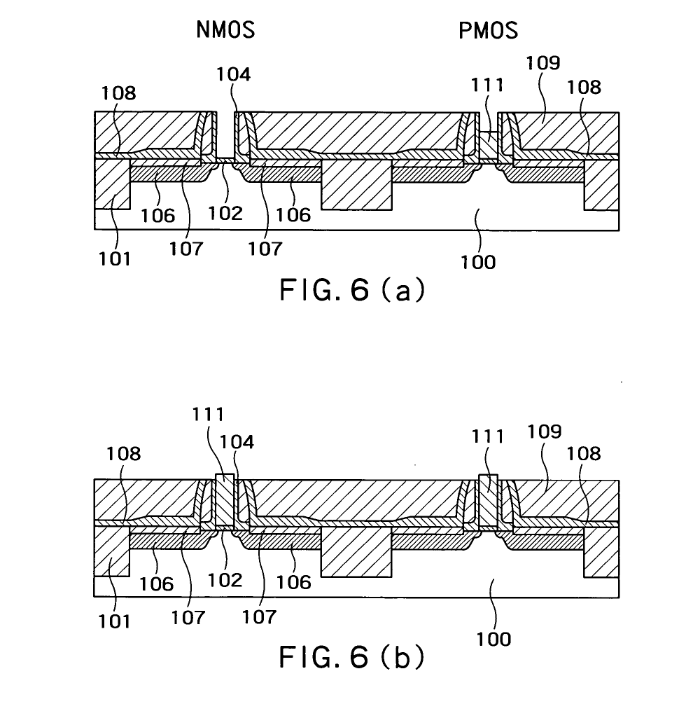

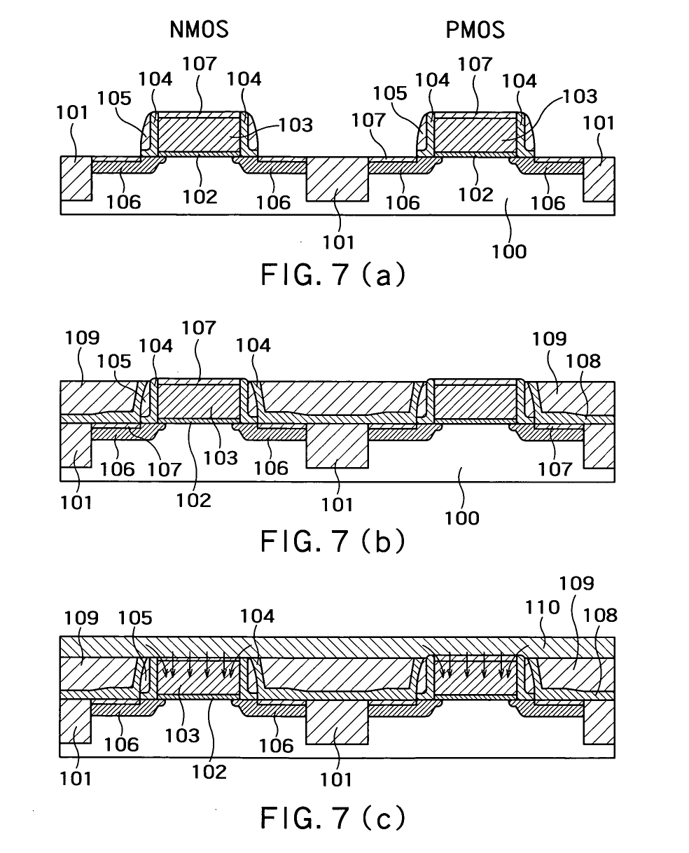

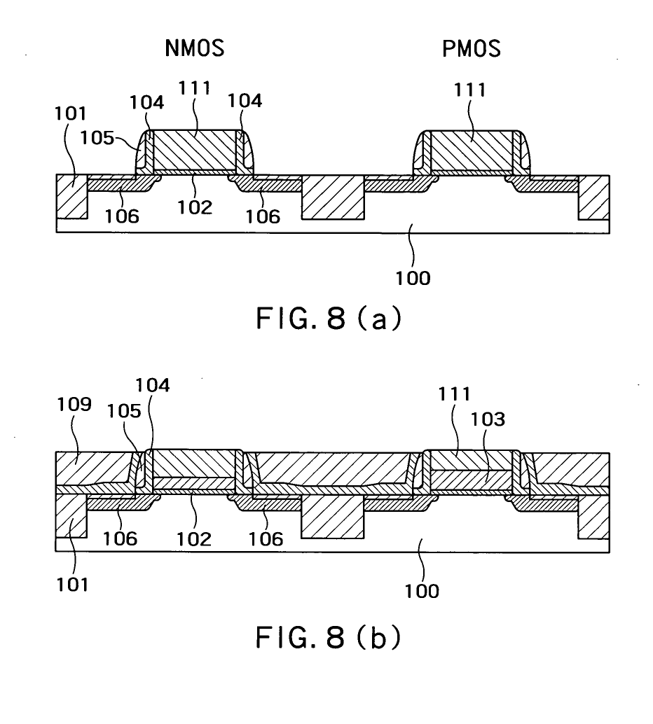

FIGS. 5(a), 5(b), 5(c) and FIGS. 6(a) and 6(b) are sectional views for explaining Example 1 of a method of manufacturing a semiconductor device. FIGS. 7(a), 7(b) and 7(c) and FIGS. 8(a) and 8(b) are sectional views for explaining Example 2. The gate widths in Examples 1 and 2 differ from each other.

First, as shown in FIG. 5(a) and FIG. 7(a), a silicon oxynitride film 102 serving as a gate insulating film is formed on a single crystal silicon substrate 100 including element isolation 101, and a silicon film 103 is deposited thereon.

Subsequently, anisotropy etching is performed on the silicon film 103 so as to have a desired pattern, thereby forming a gate electrode. At this time, in Example 1 shown in FIGS. 5(a) to 6(b), the width of the gate electrode is set to be, for example, 30 nm, and in Example 2 shown in FIGS. 7(a) to 8(b), the width of the gate electrode is set to be, for example, 1 μm.

Thereafter, a diffusion layer is formed by implanting As⁺ ions, for example, to an n-type MOS region, implanting B⁺ ions to a p-type MOS region, and performing a heat treatment at a temperature of 800° C. for five seconds.

Then, a silicon oxide film 104 and a silicon nitride film 105 are deposited and etched back, thereby obtaining a structure in which the side portions of an electrode pattern are surrounded by the silicon oxide film 104 and the silicon nitride film 105.

Furthermore, a diffusion layer 106 is formed by implanting P⁺ ions, for example, to the n-type MOS region, implanting B⁺ ions to the p-type MOS region, and performing a heat treatment at a temperature of 1,030° C. for five seconds.

Thereafter, a Ni film (10 nm), for example, is deposited on the entire surface, and a heat treatment is performed at a temperature of 350° C. for about 30 seconds, thereby causing Ni to react with the silicon substrate. Subsequently, unreacted part of the Ni film is removed by using, for example, a mixed solution containing sulfuric acid and oxygenated water. Subsequently, a heat treatment is performed at a temperature of 500° C. for about 30 seconds. As a result, a Ni silicide layer 107 is formed on the gate electrode and the diffusion layer.

Subsequently, as shown in FIG. 5(b) and FIG. 7(b), a silicon nitride film 108 (30 nm) and an interlayer film 109 (250 nm), for example, are formed on the entire surface, and then the interlayer film 109 is flattened by, for example, chemical mechanical polishing (CMP) until the surface of the silicon nitride film 108 is exposed. Thereafter, the silicon nitride film 108 is removed by an etch back method so that the Ni silicide layer 107 or the silicon film 103 at the surface of the gate electrode is exposed. It is possible to remove the silicon nitride film 108 on the gate electrode by CMP.

Then, as shown in FIG. 5(c) and FIG. 7(c), a Ni film 110 (40 nm), for example, is deposited on the entire surface.

Thereafter, Ni is caused to react with silicon by a heat treatment. With respect to the reaction of Ni (nickel) and Si (silicon), since the diffusion coefficient of Ni is greater than that of silicon, the thickness of the Ni-silicon reaction layer is substantially determined by the diffusion of Ni atoms from the Ni film to the gate electrode. Accordingly, the Ni atoms to react with silicon in the gate electrode portion diffuse into the gate electrode portion not only from the top of the gate electrode but also from the periphery portions of the gate electrode in an avalanching manner.

The silicide reaction speed also varies due to the impurity contained in the silicon film. The reason for this is said to be that the impurity segregates to the interface between the silicide and silicon, thereby interfering the reaction thereof.

Accordingly, in the case of a gate electrode having a narrow width as shown in FIG. 5(c), more Ni atoms per one silicon atom are diffused as compared with a gate electrode having a wide width as shown in FIG. 7(c) since the volume of silicon relating to the silicide reaction is smaller.

As a result, as shown in FIG. 6(a), when the silicon film of the narrow gate electrode portion is completely changed to, for example, a nickel mono-silicide film 111 (NiSi), the narrow gate electrode portion becomes a Ni-rich silicide film since Ni atoms are excessively supplied. In the worst case, the Ni-rich silicide layer during the unreacted Ni film removing step, as shown in FIG. 6(a). Furthermore, since the speed of silicidation reaction differs depending on the type of impurity contained in the silicon electrode, the thickness of the silicide layer remaining after the removal of unreacted Ni varies depending on whether it is an NMOS or a PMOS.

On the contrary, when the silicon film of the wide gate electrode portion is completely changed to, for example, a nickel mono-silicide film 111 (NiSi) as shown in FIG. 8(b), a sufficient amount of Ni atoms is not supplied to the wide gate electrode portion so as to completely change the wide gate electrode portion to a silicide film, as shown in FIG. 8(b). As a result, the lower portion of the gate electrode remains to be the silicon film 103. Also in this case, the thickness of Ni silicide layer formed varies depending on the type of impurity.

Although the two cases where gate widths are different from each other are shown in Examples 1 and 2, the same phenomena would occur when the gate widths are the same but the longitudinal lengths differ from each other, and when the densities of the gate electrodes differ from each other.

The present inventor has made the present invention considering the matters unique to the present inventor.

Hereinafter, embodiments of the present invention will be described with reference to the accompanying drawings.

### First Embodiment

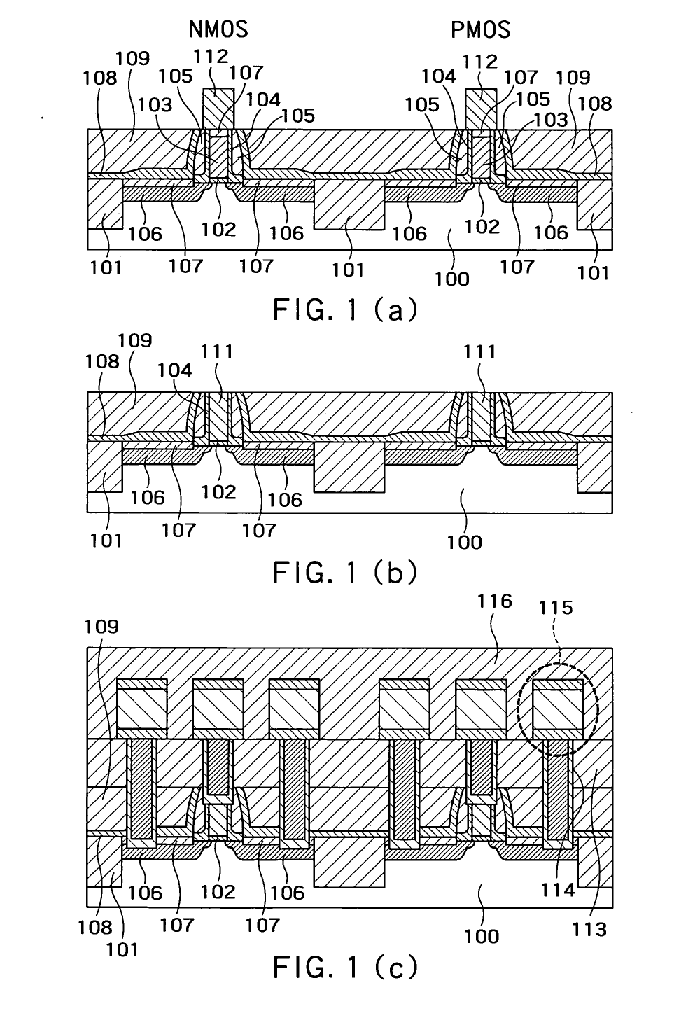

FIGS. 1(a), 1(b) and 1(c) are sectional views for explaining a method of manufacturing a semiconductor device according to a first embodiment of the present invention.

FIG. 1(a) shows a step following the step of Example 1 shown in FIG. 5(b).

As shown in FIG. 1(a), a Ni film 112 is selectively formed immediately on the gate electrode.

Although the Ni film 112 is selectively formed substantially only on the gate electrode, the edges of the metal film can slightly extend off over the interlayer film.

As a result, it is possible to control the amount of supply of Ni atoms, which are diffusion species, by the amount of consumption of silicon atoms of the gate electrode.

The Ni film 112 (40 nm) is formed by performing electroless plating using, for example, NiSO₄ as a plating liquid with a plating bath temperature of 60 to 80° C. and a plating liquid pH of 5 to 10.

Subsequently, as shown in FIG. 1(b), it is possible to form a uniform Ni silicide electrode 111 without depending on the pattern width by performing, for example, a heat treatment at a temperature of 500° C. for 60 seconds.

At this time, the speed of the reaction of Ni and silicon differs depending on the type of impurity. This can be solved by taking a sufficient heat treatment time so that all Ni atoms react with silicon. The reason for this is that the amount of Ni diffusion used for the reaction with silicon is limited to the amount selectively formed immediately above the gate electrode, and that therefore even if a long heat treatment time is taken, it is not necessary to worry about the Ni atoms flowing from the periphery portion of the gate electrode.

Then, as shown in FIG. 1(c), a desired contact pattern is formed on the second interlayer film 113, and a Ti/TiN/W film, for example, is embedded within the contact pattern and flattened by CMP, thereby forming contacts 114.

Thereafter, Al wiring 115 for electrically connecting the contacts 114 is formed, and a third interlayer film 116 is deposited and flattened by CMP.

It is possible to form a CMOS transistor including a silicide electrode by the aforementioned process.

### Second Embodiment

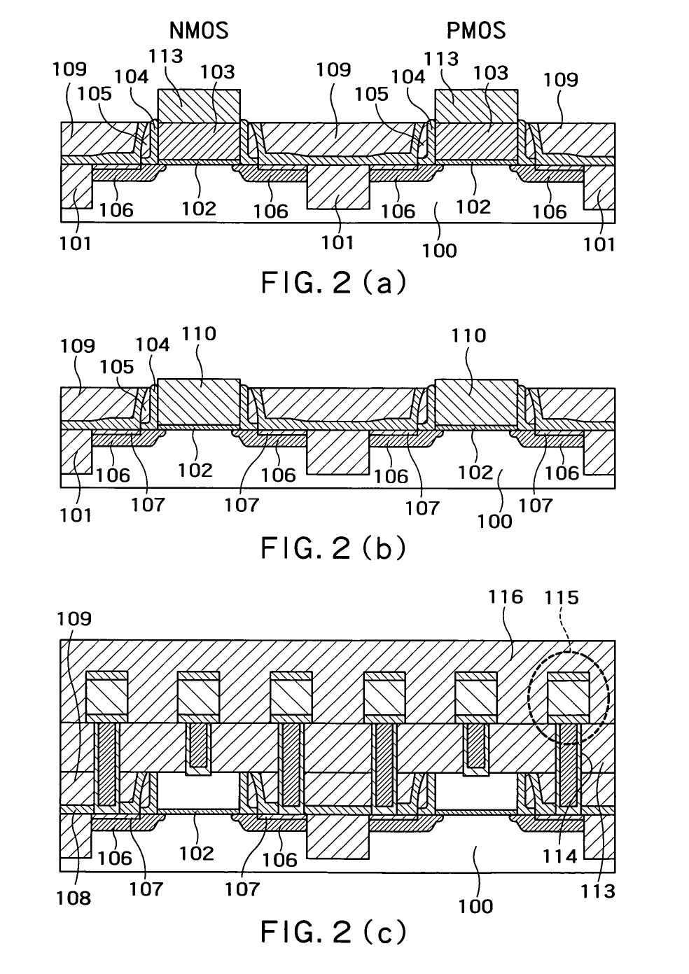

FIGS. 2(a), 2(b), and 2(c) are sectional views for explaining a method of manufacturing a semiconductor device according to a second embodiment of the present invention.

FIG. 2(a) shows a step following the step of Example 2 shown in FIG. 7(b).

The explanation of the second embodiment relating to FIGS. 2(a), 2(b) and 2(c) is similar to the explanation of the first embodiment relating to FIGS. 1(a), 1(b), and 1(c). The difference therebetween lies in that although the width of the gate electrode is 30 nm, for example, in the first embodiment, it is 1 μm, for example, in the second embodiment.

Although a polycrystalline silicon film is used to form a gate electrode in the first and the second embodiments, it is also possible to use germanium or a compound of silicon and germanium. In such a case, a metal germanium compound can be formed instead of a metal silicon compound.

Furthermore, although Ni is used to form a metal silicide in the first and the second embodiments, it is possible to use any of Er, Tm, Pd, Pt, Co, Rh, Ir, W and Mo, or any combination of these materials.

Moreover, although the Ni film is formed by electroless plating in the first and the second embodiments, any other method can be used as long as a film can be reliably formed.

In addition, although nickel mono-silicide (NiSi) is used as a metal silicide in the first and the second embodiments, it is also possible to use Ni₂Si, Pt₂Si, PtSi, Pd₂Si, PdSi, Co₂Si, CoSi, CoSi₂, ErSi, ErSi_{1.7}, TmSi, and so on.

Further, the material to form the silicide on the gate electrode can be different from the material to form the silicide on the diffusion layer.

Although a silicon oxynitride film is used as the gate insulating film in this embodiment, it is also possible to use a silicon oxide film or a silicon nitride film. The formation method thereof can be thermal oxynitriding, CVD, etc. Any other formation method can be used in the execution of the present invention.

The material of the gate insulating film is not limited to a silicon oxide film, but can be an insulating film of a material having a higher dielectric constant than silicon oxide, such as an oxide of Hf, Zr, Ti, Ta, Al, Sr, Y, La, and so on, or an oxide of such a material and silicon, such as ZrSiₓO_{y}. In addition, a stacked layer of these oxides can also be used. In more detail, the above will be explained as follows from a different point of view:

The gate insulating film can be made as a first film, a second film or a third film,

the first film is selected from a first oxide film group consisting of oxide films of Hf, Zr, Ti, Ta, Al, Sr, Y, and La,

the second film is selected from a second oxide film group consisting of oxide films of silicon and any of Hf, Zr, Ti, Ta, Al, Sr, Y, and La, and

the third film is a stacked film of at least two films selected from the first and the second oxide film groups.

It is also possible to combine the aforementioned first and second embodiments.

Even if different gate electrode widths exist, it is possible to form uniform silicide electrodes at the same time without depending of the pattern width.

### Third Embodiment

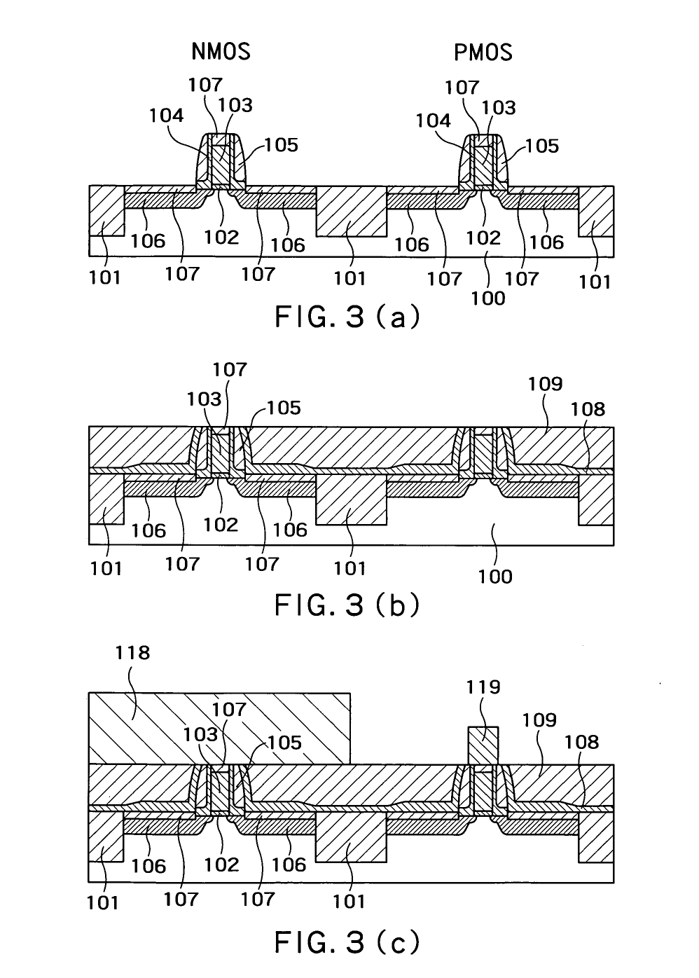

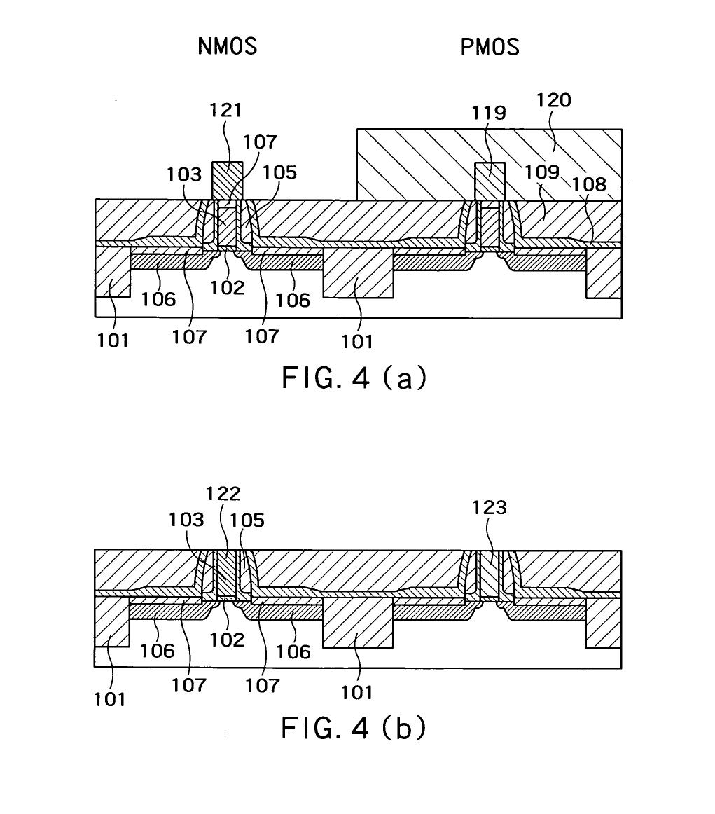

FIGS. 3(a), 3(b), and 3(c) and FIGS. 4(a) and 4(b) are sectional views for explaining a method of manufacturing a semiconductor device according to a third embodiment of the present invention.

The third embodiment shows the case where the present invention is applied to a process of forming a gate electrode of a MIS type transistor.

First, as shown in FIG. 3(a), a silicon oxynitride film 102 serving as a gate insulating film is formed on a single crystal silicon substrate 100 including element isolation 101, and a silicon germanium film is deposited thereon.

Then, anisotropy etching is performed on the silicon germanium film to have a desired pattern, thereby forming a gate electrode.

Thereafter, the formation of a diffusion layer 106 is prepared by, for example, implanting As⁺ ions to an n type MOS region, implanting B⁺ ions to a p type MOS region, and performing a heat treatment at a temperature of 800° C. for five seconds.

Then, after a silicon oxide film 104 and a silicon nitride film 105 are deposited, these films are etched back to obtain a structure in which the sidewall portions of an electrode pattern are surrounded by the silicon oxide film 105 and the silicon nitride film 104.

Furthermore, a diffusion layer 106 is formed by, for example, implanting P⁺ions to the n type MOS region, implanting B⁺ions to the p type MOS region, and performing a heat treatment at a temperature of 1,030° C. for five seconds.

Subsequently, a Ni film (10 nm), for example, is deposited on the entire surface, a heat treatment is performed at a temperature of 350° C. for about 30 seconds to cause Ni to react with the silicon substrate, and the unreacted Ni film is removed by using a mixed solution containing sulfuric acid and oxygenated water. Thereafter, a heat treatment is performed at a temperature of 500° C. for about 30 seconds. As a result, a Ni silicide layer 107 is formed on the gate electrode and the diffusion layer.

Thereafter, as shown in FIG. 3(b), for example, a silicon nitride film 108 (30 nm) and an interlayer film 109 (250 nm) are formed on the entire surface, and the interlayer film 109 is flattened by chemical mechanical polishing (CMP) until the surface of the silicon nitride film 108 is exposed. Subsequently, the silicon nitride film 108 is removed by an etch back method so as to expose the Ni silicide layer 107 or the silicon germanium film 117 at the surface of the gate electrode. The silicon nitride film 108 on the gate electrode can be removed by CMP.

Then, as shown in FIG. 3(c), the entire surface of the substrate is coated with a resist film 118, and exposure and development are performed so as to substantially cover only the n type MOS region with the resist film 118. Thereafter, a Pd film (50 nm) 119 is formed by electroless plating on the gate in the p type MOS region, which is not covered by the resist film.

Subsequently, as shown in FIG. 4(a), the resist film 118 is removed, the entire surface of the substrate is coated with a resist film 120 again, and exposure and development are performed so as to substantially cover only the p type MOS region with the resist film 120. Then, an Er film (50 nm) 121 is formed by electroless plating, for example, on the gate in the n type MOS region, which is not covered by the resist film.

Thereafter, as shown in FIG. 4(b), the resist film 120 is removed. Then, a heat treatment is performed at a temperature of, for example, 500° C., thereby forming a Er silicide or Er germanide area 122 in the n type MOS region due to the reaction of Er and silicon or germanium, and forming a Pd silicide or Pd germanide area 123 in the p type MOS region due to the reaction of Pd and silicon or germanium.

The work functions of Er silicide (and Er germanide) and Pd silicide (and Pd germanide) are about 4.1 eV and 4.9 eV, respectively. Accordingly, it is possible to form a CMOS transistor in which a gate electrode material having a work function of 4.3 eV or less is used in the n type MOS region, and a gate electrode material having a work function of 4.8 eV or less is used in the p type MOS region.

With respect to the Pd film in the third embodiment formed by electroless plating, it is possible to form a Pd film intentionally containing B by using a boron compound such as dimethyl amine borane (DMAB: (CH₃)₂NHBH₃) and so on as a reducing agent. As a result, it is possible to diffuse B, which has a work function of 4.8 eV or more, at the interface of the insulating film at the same time as Pd in the later step, thereby further increasing the work function of the gate electrode in the p type MOS region.

In the aforementioned embodiment, it is possible to perform selective CVD as other method of performing plating.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A method of manufacturing a semiconductor device including a MOS transistor, comprising:
forming a gate electrode on a semiconductor substrate via a gate insulating film;
performing ion implantation on the semiconductor substrate using the gate electrode as a mask, and performing a heat treatment, thereby forming a diffusion layer in the semiconductor substrate;
depositing an insulating film on the gate electrode and the semiconductor substrate to bury the gate electrode in the insulating film;
flattening the insulating film to expose an upper surface of the gate electrode;
selectively forming; and
changing a material of the gate electrode to a metal compound using a metal in the metal film.

2. The method of manufacturing a semiconductor device according to claim 1, wherein the metal in the metal film is Er, Tm, Ni, Pd, Pt, Co, Rh, Ir, W, Mo, or any combination thereof.

3. The method of manufacturing a semiconductor device according to claim 1, wherein the material of the gate electrode is changed to a metal silicon compound or a metal germanium compound.

4. The method of manufacturing a semiconductor device according to claim 1, wherein a channel direction width of the metal film is greater than that of the gate electrode.

5. The method of manufacturing a semiconductor device according to claim 1, wherein the material of the gate electrode is changed to the metal compound by a heat treatment.

6. The method of manufacturing a semiconductor device according to claim 1, wherein a second interlayer film is deposited, a contact hole is formed in the second interlayer film, a conductor is buried in the contact hole, and the conductor is caused to contact with the gate electrode of the metal compound.

7. The method of manufacturing a semiconductor device according to claim 1, wherein the gate insulating film is silicon oxynitride film, a silicon oxide film or a silicon nitride film.

8. The method of manufacturing a semiconductor device according to claim 1, wherein the gate insulating film is a first film, a second film or a third-film,
the first film being any of a first oxide film group of oxide films of Hf, Zr, Ti, Ta, Al, Sr, Y, and La,
the second film being any of a second oxide film group of oxide films of silicon and any of Hf, Zr, Ti, Ta, Al, Sr, Y, and La, and
the third film being a stacked film of at least any of two films of the first and the second oxide film groups.

9. The method of manufacturing a semiconductor device according to claim 1, wherein the metal film is formed on the gate electrode in such a manner that the metal film is formed on silicide formed at an upper portion of the gate electrode.

10. The method of manufacturing a semiconductor device according to claim 9, wherein the suicide is NiSi, Ni₂Si, Pt₂Si, PtSi, Pd₂Si, PdSi, Co₂Si, CoSi, CoSi₂, ErSi, ErSi_{1.7} or TmSi.

11. The method of manufacturing a semiconductor device according to claim 10, wherein the silicide is also formed on the diffusion layer.

12. The method of manufacturing a semiconductor device according to claim 11, wherein the suicide on the gate electrode and the silicide on the diffusion layer are an identical or different material.

13. The method of manufacturing a semiconductor device according to claim 1, wherein the semiconductor device includes at least an NMOS transistor and a PMOS transistor, and they are formed side by side.

14. A method of manufacturing a semiconductor device including at least a first MOS transistor and a second MOS transistor, comprising:
in order to form each of the first MOS transistor and the second MOS transistor,
forming a gate electrode on a semiconductor substrate via a gate insulating film;
performing ion implantation on the semiconductor substrate using the gate electrode as a mask, and performing a heat treatment, thereby forming a diffusion layer in the semiconductor substrate;
depositing an insulating film on the gate electrode and the semiconductor substrate to bury the gate electrode in the insulating film; and
flattening the insulating film to expose an upper surface of the gate electrode,
in order to manufacture the first MOS transistor,
selectively forming to change a material of the gate electrode to a first metal compound using the first metal film, and
in order to manufacture the second MOS transistor,
selectively forming to change a material of the gate electrode to a second metal compound using the second metal film.

15. The method of manufacturing a semiconductor device according to claim 14, wherein the first metal film is formed of a material selected from the group consisting of Er, Tm, Ni, Pd, Pt, Co, Rh, Ir, W and Mo, or any combination of these materials.

16. The method of manufacturing a semiconductor device according to claim 14, wherein the second metal film is Ni, Pd, Pt, Co, Rh, Ir, or any combination of these materials.

17. The method of manufacturing a semiconductor device according to claim 15, wherein the second metal film is Ni, Pd, Pt, Co, Rh, Ir, or any combination of these materials.

18. The method of manufacturing a semiconductor device according to claim 14, wherein the first metal film and the second metal film are formed on silicide formed at upper portions of the gate electrodes.

19. The method of manufacturing a semiconductor device according to claim 18, wherein the suicide is NiSi, Ni₂Si, Pt₂Si, PtSi, Pd₂Si, PdSi, Co₂Si, CoSi, CoSi₂, ErSi, ErSi_{1.7}, or TmSi.

20. The method of manufacturing a semiconductor device according to claim 14, wherein the first MOS transistor is an NMOS transistor, and the second MOS transistor is a PMOS transistor.
